(19) United States
(12) Patent Application Publication
(10) Pub. No.: US 2025/0201685 A1
(43) Pub. Date: Jun. 19, 2025

(54) SEMICONDUCTOR PACKAGE

(71) Applicant: Samsung Electronics Co., Ltd., Suwon-si (KR)

(72) Inventors: Jinwoo Park, Suwon-si (KR); Unbyoung Kang, Suwon-si (KR)

(21) Appl. No.: 18/908,912

(22) Filed: Oct. 8, 2024

(30) Foreign Application Priority Data
Dec. 18, 2023 (KR) 10-2023-0184330

(51) Int. Cl. H01L 23/498; H01L 25/065; H10B 80/00

(52) U.S. Cl. CPC H01L 23/49816; H01L 25/0655; H10B 80/00

(57) ABSTRACT

A semiconductor package includes: a package substrate; a first interposer and a second interposer on the package substrate, the first interposer and the second interposer being spaced apart from each other in a horizontal direction parallel to an upper surface of the package substrate; a first logic chip and first memory chips on the first interposer; a second logic chip and second memory chips on the second interposer; and a connection chip on the first and second interposers and electrically connecting the first and second interposers. The connection chip may electrically connect the first and second logic chips, and is between the first and second logic chips.

### CROSS-REFERENCE TO RELATED APPLICATION

This application claims priority under 35 USC § 119 to Korean Patent Application No. 10-2023-0184330, filed on Dec. 18, 2023, in the Korean Intellectual Property Office (KIPO), the contents of which are incorporated by reference herein in their entirety.

### BACKGROUND

Various example embodiments of the inventive concept relate generally to a semiconductor package, and, more particularly, to a semiconductor package on which a plurality of semiconductor chips are mounted.

In a 2.5D semiconductor package structure, one interposer may be bonded on a package substrate, and a plurality of logic semiconductor chips and a plurality of memory semiconductor chips may be mounted on the one interposer. Since the plurality of logic semiconductor chips and memory semiconductor chips are disposed on the one interposer, a horizontal area of the one interposer may be increased. It is not easy to form an interposer having a large horizontal area, and thus a yield of the interposer may be low. Additionally, cracks due to stress applied to the interposer may occur in the interposer.

### SUMMARY

Various example embodiments of the inventive concept provide a semiconductor package including a plurality of interposers.

According to some example embodiments, there is provided a semiconductor package. The semiconductor package may include a package substrate; a first interposer and a second interposer on the package substrate, the first interposer and the second interposer being spaced apart from each other in a horizontal direction; a first logic chip and first memory chips on the first interposer; a second logic chip and second memory chips on the second interposer; and a connection chip connecting the first and second interposers on the first and second interposers. The connection chip may connect the first and second logic chips, and is disposed between the first and second logic chips.

According to some example embodiments, there is provided a semiconductor package. The semiconductor package may include a package substrate; a plurality of interposers arranged to be spaced apart from each other in a horizontal direction on the package substrate; at least one logic chip and a plurality of memory chips on each of the interposers; and a connection chip on at least two of the interposers, the connection chip having a bridge shape to connect the at least two interposers to each other. The connection chip may be electrically connected to the logic chips disposed on the at least two interposers.

According to some example embodiments, there is provided a semiconductor package. The semiconductor package may include a package substrate; a first interposer on the package substrate; a second interposer on the package substrate to be spaced apart from the first interposer in a horizontal direction; a first logic chip bonded on the first interposer; first memory chips bonded on the first interposer to be spaced apart from at least one sidewall of the first logic chip, and the first memory chips being electrically connected to the first logic chip; a second logic chip bonded on the second interposer, and the second logic chip disposed to face the first logic chip in the horizontal direction; second memory chips bonded on the second interposer to be spaced apart from at least one sidewall of the second logic chip, and the second memory chips being electrically connected to the second logic chip; a connection chip disposed between the first and second logic chips on the first and second interposers, the connection chip having a bridge shape to connect the first and second interposers to each other, and the connection chip including a wiring electrically connecting the first and second logic chips; and an underfill member at least partially filling a space between the first interposer and the first logic chip, a space between the first interposer and the connection chip, a space between the second interposer and the second logic chip, a space between the second interposer and the connection chip, a space between the first interposer and the package substrate, and a space between the second interposer and the package substrate.

According to example embodiments, the semiconductor package may include the plurality of interposers disposed on one package substrate. At least one logic semiconductor chip and the plurality of memory semiconductor chips may be mounted on each of the interposers. The logic chips disposed on the interposers may be electrically connected to each other by the connection chip disposed between the interposers.

Accordingly, a horizontal area of each of the interposers bonded on the package substrate may be decreased. As the horizontal area of each of the interposers is decreased, defects of each of the interposers may be decreased and a yield of the interposer may be increased. Therefore, a yield of the semiconductor package may be increased.

However, effects and advantages of the present invention may not be limited to the effects and advantages described above, and may be expanded in various ways without departing from spirit and scope of the present invention.

### BRIEF DESCRIPTION OF THE DRAWINGS

Various non-limiting, example embodiments will be more clearly understood from the following detailed description taken in conjunction with the accompanying drawings, wherein like reference numerals (when used) indicate corresponding elements throughout the several views, and in which:

FIG. 1 is a schematic plan view illustrating a semiconductor package according to example embodiments;

FIG. 2 is a schematic cross-sectional view taken along line A-A′ of FIG. 1;

FIG. 3 is a schematic cross-sectional view taken along line B-B′ of FIG. 1;

FIG. 4 is a schematic cross-sectional view illustrating a connection between logic chips and a connection chip in a semiconductor package;

FIG. 5 is a schematic plan view illustrating a semiconductor package according to example embodiments;

FIG. 6 is a schematic plan view illustrating a semiconductor package according to example embodiments;

FIG. 7 is a schematic plan view illustrating a semiconductor package according to example embodiments;

FIG. 8 is a schematic plan view illustrating a semiconductor package according to example embodiments; and

FIGS. 9 to 22 are schematic cross-sectional views and plan views illustrating intermediate processes in an illustrative method of manufacturing a semiconductor package according to example embodiments.

### DETAILED DESCRIPTION

Hereinafter, various example embodiments will be described in detail with reference to the accompanying drawings.

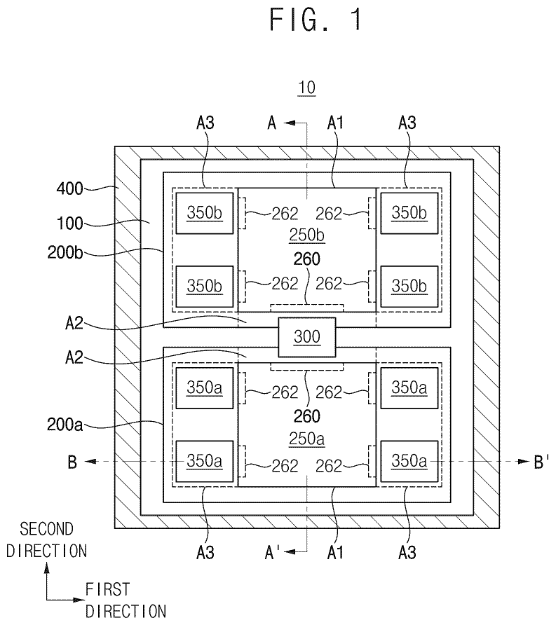

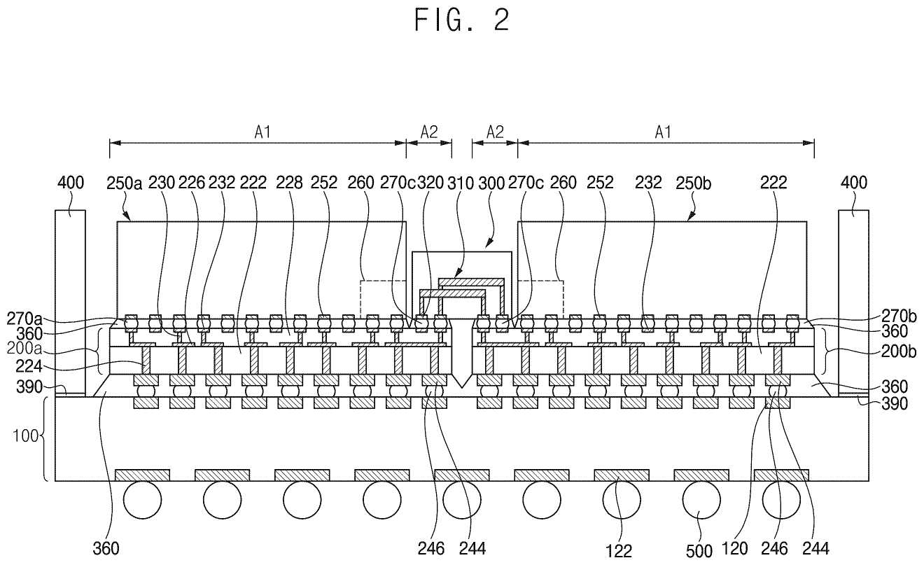

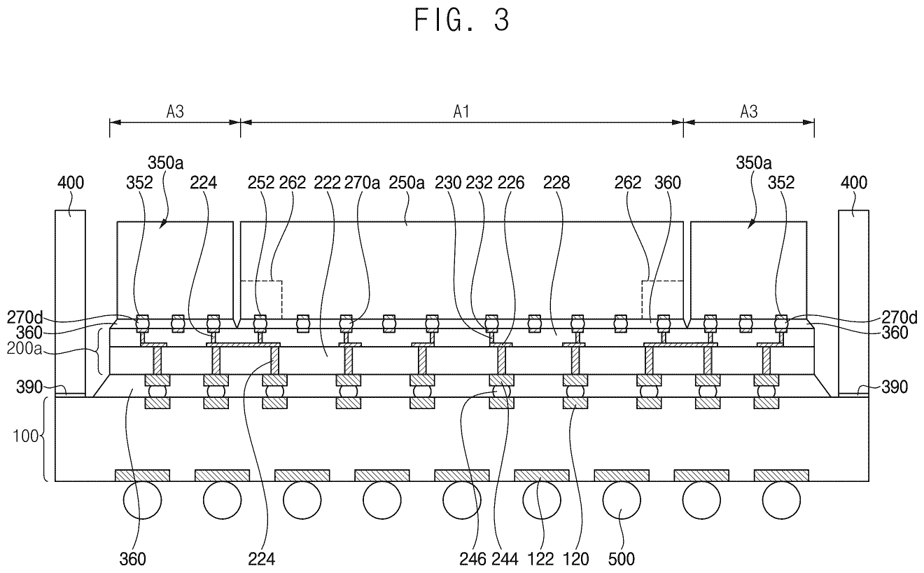

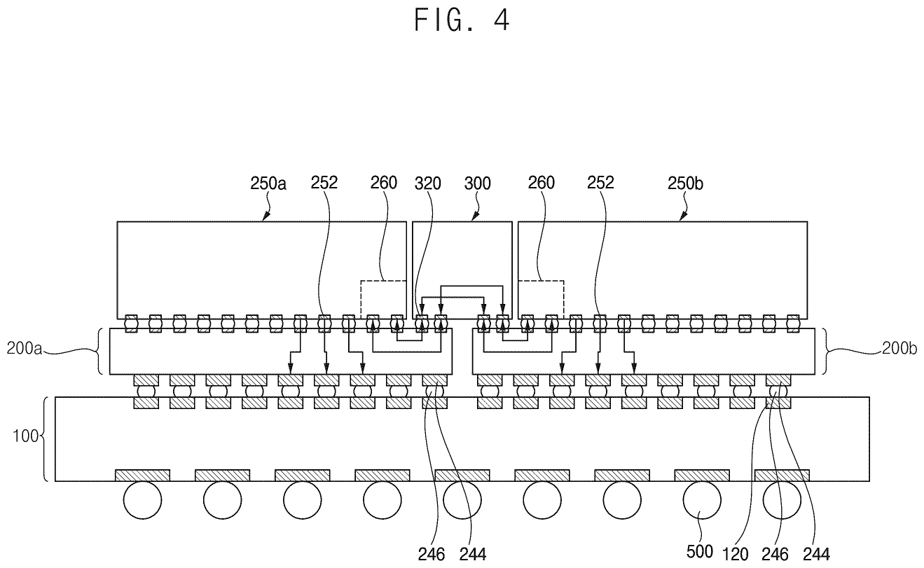

FIG. 1 is a schematic plan view illustrating a semiconductor package according to example embodiments. FIG. 2 is a schematic cross-sectional view taken along line A-A′ of FIG. 1. FIG. 3 is a schematic cross-sectional view taken along line B-B′ of FIG. 1. FIG. 4 is a schematic cross-sectional view illustrating a connection between logic chips and a connection chip in the semiconductor package.

Referring to FIGS. 1 to 4, a semiconductor package 10 may include a package substrate 100, a plurality of interposers 200a and 200b being spaced apart horizontally (i.e., in a direction parallel to an upper surface of the package substrate 100) from each other on the package substrate 100, at least one logic chip 250a and 250b and a plurality of memory chips 350a and 350b disposed on each of the interposers 200a and 200b, and a connection chip 300 on the interposers 200a and 200b for electrically connecting the interposers 200a and 200b. The connection chip 300 is configured to overlap a portion of each of the logic chips 250a and 250b in the vertical direction (i.e., in a direction perpendicular to the upper surface of the package substrate 100). The term “overlap” (or “overlapping,” or like terms), as may be used herein, is intended to broadly refer to a first element that intersects with at least a portion of a second element in the vertical direction, but does not require that the first and second elements be completely aligned with one another in a horizontal plane. The term “connecting” (or “connected,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items.

In example embodiments, the semiconductor package 10 may be a device having a stacked chip structure in which a plurality of chips are stacked in the vertical direction. For example, the semiconductor package 10 may have a 2.5D semiconductor package structure.

In example embodiments, the logic chips 250a and 250b included in the semiconductor package 10 may be an ASIC as a host such as a central processing unit (CPU), graphics processing unit (GPU), or system on a chip (SoC). The memory chips 350a and 350b included in the semiconductor package 10 may include a high-bandwidth memory (HBM) device.

The package substrate 100 may be a substrate having an upper surface and a lower surface opposite the upper surface. The package substrate 100 may include internal wirings for electrically connecting the interposers. The upper surface of the package substrate 100 may include first substrate pads 120, and the lower surface of the package substrate 100 may include second substrate pads 122. External bumps 500 may be formed on the second substrate pads 122.

In example embodiments, the package substrate 100 may include a printed circuit board (PCB). The printed circuit board may be a multilayer circuit board including via structures and conductive patterns therein.

The plurality of interposers 200a and 200b may be bonded on one package substrate 100.

In example embodiments, the number of interposers bonded on the package substrate 100 may be equal to the number of logic chips 250a and 250b included in the semiconductor package 10. In some example embodiments, the number of interposers bonded on the package substrate 100 may be smaller than the number of logic chips 250a and 250b included in the semiconductor package 10.

Hereinafter, two interposers disposed on the one package substrate 100 may be described, and the two interposers are referred to as a first interposer 200a and a second interposer 200b, respectively. It will be understood that, although ordinal terms such as “first,” “second,” etc., may be used herein to describe various elements, these elements should not be limited by such terms. Rather, these terms are used merely to distinguish one element from another and are not necessarily intended to convey a particular order of the elements, unless described as such. The logic chip 250a disposed on the first interposer 200a is referred to as a first logic chip 250a, and the logic chip 250b disposed on the second interposer 200b is referred to as a second logic chip 250b. Additionally, the memory chips disposed on the first interposer 200a are referred to as first memory chips 350a, and memory chips disposed on the second interposers 200b are referred to as second memory chips 350b. However, the number of interposers disposed on the one package substrate may not be limited thereto, and three or more interposers may be disposed on the package substrate.

In example embodiments, the interposers 200a and 200b disposed on the package substrate 100 may have the same horizontal area relative to each other, although embodiments are not limited thereto. For example, the first and second interposers 200a and 200b may have the same horizontal area to each other. When two interposers 200a and 200b are disposed on the package substrate 100, the horizontal area of each of the first and second interposers 200a and 200b may be less than ½ of a horizontal area of the package substrate 100.

In general, when n (n are 2 or more) interposers are arranged on the package substrate 100, each of the interposers (i.e. an individual interposer) may be smaller than at least 1/n of the horizontal area of the package substrate 100. Therefore, compared to a case where one interposer is disposed on the package substrate 100, the horizontal area of the each of the interposers disposed on the package substrate 100 may be decreased. For example, the horizontal area of the each of the interposers disposed on the package substrate 100 may be less than at least ½ of a horizontal area of the interposer of the case where the one interposer is disposed on the package substrate 100.

In example embodiments, in the plan view, the first and second interposers 200a and 200b may be disposed on the package substrate 100 so that a first direction, parallel to the upper surface of the substrate 100, may be a longitudinal direction. The first and second interposers 200a and 200b may be arranged in the second direction parallel to the upper surface of the substrate 100 and perpendicular to the first direction, and may be spaced apart from each other in the second direction.

In example embodiments, each of the first and second interposers 200a and 200b may be a silicon interposer having through silicon vias (TSVs) 224. Each of the first and second interposers 200a and 200b may include a silicon base portion 222, the through silicon via 224 penetrating (i.e., extending into) the silicon base portion 222, a pad pattern 226 for connecting the through silicon via 224, an insulation layer 228, and a wiring pattern 230. The wiring pattern 230 may be, e.g., a redistribution layer (RDL). A first bonding pad 232 may be formed on the wiring pattern 230.

The silicon base portion 222 may include single crystal silicon. The through silicon via 224 may include metal, e.g., aluminum (Al), copper (Cu), tin (Sn), nickel (Ni), gold (Au), platinum (Pt), or alloys of thereof. The redistribution layer may include metal, e.g., aluminum (Al), copper (Cu), tin (Sn), nickel (Ni), gold (Au), platinum (Pt), or alloys thereof.

Each of the first and second interposers 200a and 200b may have a lower surface and an upper surface opposite the lower surface. The first bonding pad 232 may be exposed by the upper surface of each of the first and second interposers 200a and 200b. A second bonding pad 244 may be exposed by the lower surface of each of the first and second interposers 200a and 200b. The term “exposed” (or “exposes,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

Each of the first and second interposers 200a and 200b may have a first chip mounting area A1 on which the logic chips 250a and 250b are mounted, a second chip mounting area A2 on which the connection chip 300 is mounted, and a third chip mounting area A3 on which the memory chips 350a and 350b are mounted.

In the plan view, the second chip mounting area A2 may be disposed at an edge of each of the first and second interposers 200a and 200b adjacent to one side of the first chip mounting area A1. The second chip mounting area A2 disposed on the first interposer 200a may be facing the second chip mounting area A2 disposed on the second interposer 200a, separated from one another in the second direction. In the plan view, the third chip mounting area A3 may be disposed at an edge of the each of the first and second interposers 200a and 200b adjacent to two opposing sides of the first chip mounting area A1.

In example embodiments, in the plan view, the third chip mounting area A3 may be adjacent to both sides of the first chip mounting area Al in the first direction. Additionally, the second chip mounting area A2 may be adjacent to one side of the first chip mounting area A1 in the second direction.

Wirings for electrically connecting between the logic chips 250a and 250b and the package substrate 100, wirings for electrically connecting between the logic chips 250a and 250b and the memory chips 350a and 350b, and wirings for electrically connecting the logic chips 250a and 250b and the connection chip 300 may be included in the first chip mounting area A1 of the first and second interposers 200a and 200b. Wiring for electrically connecting between the logic chips 250a and 250b and the connection chip 300 may be included in the second chip mounting area A2 of the first and second interposers 200a and 200b. Wirings for electrically connecting between the memory chips 350a and 350b and the package substrate 100, and wirings for electrically connecting the logic chips 250a and 250b and the memory chips 350a and 350b may be included in the third chip mounting area A3.

The first and second interposers 200a and 200b may be provided (e.g., mounted) on the package substrate 100 using conductive bumps 246. Each of the conductive bumps 246 may be interposed between the second bonding pad 244 of the first and second interposers 200a and 200b and the first substrate pad 120 of the package substrate 100. The conductive bump 246 may include, e.g., a C4 bump or a C2 bump. For example, the conductive bump 246 may include copper pillars and C4 solder. The second bonding pad 244 of the first and second interposers 200a and 200b may be electrically connected to the first substrate pad 120 of the package substrate 100 by the conductive bumps 246.

The first and second bonding pads 232 and 244 may include a metal. For example, the metal may include nickel (Ni), antimony (Sb), bismuth (Bi), zinc (Zn), indium (In), palladium (Pd), platinum (Pt), aluminum (Al), and copper. (Cu), molybdenum (Mo), titanium (Ti), gold (Au), silver (Ag), chromium (Cr), tin (Sn), or alloys thereof.

In some example embodiments, each of the first and second interposers 200a and 200b may be a redistribution interposer having a plurality of redistribution layers formed in an insulation layer.

The first and second logic chips 250a and 250b may be provided (e.g., mounted) on the first bonding pads 232 of the first chip mounting areas A1 of the first and second interposers 200a and 200b, respectively. The connection chip 300 may be provided on the first bonding pads 232 of the second chip mounting areas A2 of the first and second interposers 200a and 200b. The first and second memory chips 350a and 350b may be provided on the first bonding pads 232 of the third chip mounting areas A3 of the first and second interposers 200a and 200b, respectively.

The first logic chip 250a may be bonded on an upper surface of the first chip mounting area A1 of the first interposer 200a. The second logic chip 250b may be bonded on the upper surface of the first chip mounting area A1 of the second interposer 200b. Active surfaces of the first and second logic chips 250a and 250b where first chip pads 252 are formed may face the upper surfaces of the first and second interposers 200a and 200b, respectively.

The first chip pads 252 of the first logic chip 250a may be electrically connected to the first bonding pads 232 of the first interposer 200a by first solder bumps 270a. The first chip pads 252 of the second logic chip 250b may be electrically connected to the first bonding pads 232 of the second interposer 200b by second solder bumps 270b. The first and second solder bumps 270a and 270b may include, e.g., a micro bump. For example, the first and second solder bumps 270a and 270b may have a stacked structure of a copper pillar, a micro solder, and a copper pillar.

Each of the first and second logic chips 250a and 250b may include a physical area (PHY) 262 in which wirings for electrically connecting the memory chips 350a and 350b are disposed. In addition, each of the first and second logic chips 250a and 250b may include a wiring area 260 in which wirings for electrically connecting the first and second logic chips 250a and 250b disposed on different interposers 200a and 200b are formed.

The physical area 262 of each of the first and second logic chips 250a and 250b may be adjacent to the third chip mounting area A3 in the first direction. The wiring area 260 of the first logic chip 250a and the wiring area 260 of the second logic chip 250b may be opposite to each other in the second direction. The wiring area 260 of each of the first and second logic chips 250a and 250b may be adjacent to the second chip mounting area A2. Accordingly, the wiring areas 260 of the first and second logic chips 250a and 250b may be adjacent to the connection chip 300.

The connection chip 300 may be on the first and second interposers 200a and 200b, and may be electrically connected to the first and second interposers 200a and 200b. The first and second logic chips 250a and 250b disposed on different interposers may be electrically connected to each other by the connection chip 300.

The connection chip 300 may have a bridge shape, extending from an edge of one interposer to an edge of an adjacent interposer, for connecting the first and second interposers 200a and 200b spaced apart in the second direction.

The connection chip 300 may include connection wirings 310 for electrically connecting the first logic chip 250a and the second logic chip 250b. Additionally, the connection chip 300 may include third chip pads 320 connected to the connection wirings 310.

An active surface of the connection chip 300 where the third chip pads 320 are formed may face the upper surfaces of the first and second interposers 200a and 200b in the vertical direction. Accordingly, the first logic chip 250a on the first interposer 200a and the second logic chip 250b on the second interposer 200b may be electrically connected by the connection chip 300.

The connection chip 300 may be disposed on the second chip mounting area A2 of the first interposer 200a, the second chip mounting area A2 of the second interposer 200b, and a region between the second chip mounting areas A2 of the first and second interposers. The connection chip 300 may face the second chip mounting area A2 of the first interposer 200a, the second chip mounting area A2 of the second interposer 200b, and the and region between the second chip mounting area A2 of the first and second interposers in a vertical direction perpendicular to the upper surface of the package substrate 100.

The connection chip 300 may be disposed between an edge of the first logic chip 250a corresponding to the wiring area 260 of the first logic chip 250a and an edge of the second logic chip 250b corresponding to the wiring area 260 of the second logic chip 250b.

The third chip pads 320 of the connection chip 300 may be connected to the first bonding pads 232 of the first interposer 200a and the first bonding pads 232 of the second interposer 200b by third solder bumps 270c. The third solder bump 270c may include, e.g., a micro bump. For example, the third solder bump 270c may have a stacked structure of a copper pillar, a micro solder, and a copper pillar.

The first memory chips 350a may be provided on the third chip mounting area A3 of the first interposer 200a. The second memory chips 350b may be provided on the third chip mounting area A3 of the second interposer 200b.

Active surfaces of the first and second memory chips 350a and 350b where the second chip pads 352 are formed may face the upper surfaces of the first and second interposers 200a and 200b in the vertical direction.

The second chip pads 352 of each of the first memory chips 350a may be electrically connected to the first bonding pads 232 of the first interposer 200a by fourth solder bumps 270d. The second chip pads 352 of each of the second memory chips 350b may be electrically connected to the first bonding pads 232 of the second interposer 200b by the fourth solder bumps 270d. The fourth solder bump 270d may include a micro bump. For example, the fourth solder bump 270d may have a stacked structure of a copper pillar, a micro solder, and a copper pillar.

Each of the first memory chips 350a may be adjacent to the physical area 262 of the first logic chip 250a in the first direction. Each of the second memory chips 350b may be adjacent to the physical area 262 of the second logic chip 250b in the first direction.

As described above, the first logic chip 250a and the first memory chips 350a may be provided (e.g., mounted) on the first interposer 200a. The second logic chip 250b and the second memory chips 350b may be provided on the second interposer 200b. The connection chip 300 for connecting the first and second logic chips 250a and 250b may be provided on the first and second interposers 200a and 200b to have the bridge shape. The first logic chip 250a and the first memory chips 350a may be arranged in a horizontal direction on the first interposer 200a, and the second logic chip 250b and the second memory chips 350b may be arranged in the horizontal direction on the second interposer 200b.

As shown in FIG. 4, the first logic chip 250a and the package substrate 100 may be electrically connected to each other by the first interposer 200a, and the first logic chip 250a and the connection chip 300 may be electrically connected to each other by the first interposer 200a. The second logic chip 250b and the package substrate 100 may be electrically connected to each other by the second interposer 200b, and the second logic chip 250b and the connection chip 300 may be electrically connected to each other by the second interposer 200b. Accordingly, the first and second logic chips 250a and 250b disposed on different interposers 200a and 200b may be electrically connected to each other by the connection chip 300 and the first and second interposers 200a and 200b. Additionally, the first logic chip 250a and the first memory chip 350a may be electrically connected to each other by the first interposer 200a. The second logic chip 250b and the second memory chip 350b may be electrically connected to each other by the second interposer 200b.

If one interposer is disposed on one package substrate, a horizontal area of the interposer may be great, similar to a horizontal area of the package substrate. If the horizontal area of the interposer increases, a probability of occurrence of process defects of the interposer may be increased. Therefore, a yield of the interposer may be decreased.

However, in example embodiments, as described above, the plurality of interposers 200a and 200b may be arranged on one package substrate 100 to be spaced apart from each other. Therefore, the horizontal area of each of the plurality of interposers 200a and 200b (i.e. the individual interposer) disposed on the package substrate 100 may be decreased. Accordingly, the process defects of each of the interposers 200a and 200b may be decreased, and the yield of the interposers 200a and 200b may be increased (i.e., improved). As the horizontal area of the individual interposer 200a and 200b is decreased, a size of each of the logic chips may be decreased, and thus a yield of the logic chips may be increased.

Additionally, as the horizontal area of the individual interposers 200a and 200b is decreased, the number of the logic chips and the number of memory chips provided (e.g., bonded) on the individual interposer 200a and 200b may be decreased. Therefore, crack defects (e.g., underfill cracks or bump cracks) caused by stress applied to the chips provided on the individual interposers 200a and 200b may be decreased. Accordingly, reliability defects of the semiconductor package 10 may be decreased.

An underfill member 360 may fill a space between the first interposer 200a and the package substrate 100 and a space between the second interposer 200b and the package substrate 100. The term “fill” (or “fills,” “filled,” or like terms), as may be used herein, is intended to refer broadly to either completely filling a defined space (e.g., the space between the first interposer 200a and the package substrate 100) or partially filling the defined space; that is, the defined space need not be entirely filled but may, for example, be partially filled or have voids or other spaces throughout. The underfill member 360 may fill a space between the first interposer 200a and the first logic chip 250a and a space between the second interposer 200b and the second logic chip 250b. Additionally, the underfill member 360 may fill a space between the first interposer 200a and the connection chip 300 and a space between the second interposer 200b and the connection chip 300.

For example, the underfill member 360 may include an adhesive including an epoxy material.

A stiffener structure 400 may be formed on the package substrate 100, and the stiffener structure 400 may surround an edge of the package substrate 100. An adhesive (or other attachment means) 390 may be interposed between the stiffener structure 400 and the package substrate 100, so that the stiffener structure 400 may be attached on the package substrate 100.

External bumps 500 may be provided on the second substrate pads 122. The external bumps 500 may provide electrical connection between the semiconductor package 10 and an external circuit or device.

In the semiconductor package 10, the plurality of interposers 200a and 200b may be arranged on one package substrate 100 to be spaced apart from each other, and the logic chips 250a and 250b are electrically connected to each other by the connection chip 300. Therefore, the semiconductor package may be manufactured to have high yield, and the semiconductor package may have high reliability.

An arrangement and the number of the interposers, the logic chips, and the connection chips included in the semiconductor package may be variously changed. Thereafter, various embodiments of the semiconductor package may be described.

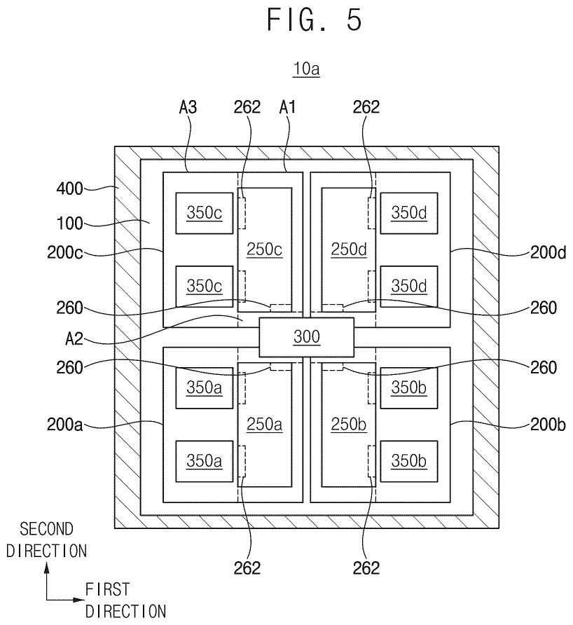

FIG. 5 is a plan view illustrating a semiconductor package according to example embodiments.

A semiconductor package 10a as shown in FIG. 5 may be the same or similar to the semiconductor package described with reference to FIGS. 1 to 4, except for an arrangement of the interposers, the logic chips, and the connection chips and the number of the interposers and the logic chips.

Referring to FIG. 5, four interposers may be disposed on the package substrate 100, and the four interposers are referred to as first to fourth interposers 200a, 200b, 200c, and 200d, respectively.

The first logic chip 250a and the first memory chips 350a may be disposed on the first interposer 200a. The second logic chip 250b and second memory chips 350b may be disposed on the second interposer 200b. A third logic chip 250c and third memory chips 350c may be disposed on the third interposer 200c. A fourth logic chip 250d and fourth memory chips 350d may be disposed on the fourth interposer 200d.

One connection chip 300 may be disposed on the first to fourth interposers 200a, 200b, 200c and 200d, and may be electrically connect the first to fourth interposers 200a, 200b, 200c, and 200d to each other. The connection chip 300 may be electrically connected to the first to fourth logic chips 250a, 250b, 250c, and 250d.

In example embodiments, a plurality of interposers 200a, 200b, 200c, and 200d disposed on the package substrate 100 may have the same horizontal area relative to each other. For example, the first to fourth interposers 200a, 200b, 200c, and 200d may have the same horizontal area.

In example embodiments, in a plan view, the first and second interposers 200a and 200b may be arranged on the package substrate 100 to be spaced apart from each other in the first direction. The third and fourth interposers 200c and 200d may be arranged on the package substrate 100 to be spaced apart from each other in the first direction. The first and third interposers 200a and 200c may be arranged on the package substrate 100 to be spaced apart from each other in the second direction. The second and fourth interposers 200b and 200d may be arranged on the package substrate 100 to be spaced apart from each other in the second direction.

Each of the first to fourth interposers 200a, 200b, 200c, and 200d may have a first chip mounting area A1 where the logic chips 250a, 250b, 250c, and 250d are mounted, a second chip mounting area A2 where the connection chip is mounted, and a third chip mounting area A3 where the memory chips 350a, 350b, 350c, and 350d are mounted.

In the plan view, the first chip mounting areas A1 of the first and third interposers 200a and 200c may be adjacent to right edges of the first and third interposers 200a and 200c, respectively. The first chip mounting areas A1 of the second and fourth interposers 200b and 200d may be adjacent to left edges of the second and fourth interposers 200b and 200d, respectively.

Accordingly, the first chip mounting areas A1 of the first and second interposers 200a and 200b may adjacent to each other in the first direction. The first chip mounting areas A1 of the third and fourth interposers 200c and 200d may be adjacent to (i.e., facing) each other in the first direction. The first chip mounting areas A1 of the first and third interposers 200a and 200c may be adjacent to each other in the second direction. The first chip mounting areas A1 of the second and fourth interposers 200b and 200d may be adjacent to each other in the second direction.

In example embodiments, in the plan view, the third chip mounting area A3 may be adjacent to one side in the first direction of the first chip mounting area A1. Additionally, the second chip mounting area A2 may be adjacent to one side in the second direction of the first chip mounting areas A1.

Each of the first to fourth logic chips 250a, 250b, 250c, and 250d may include a physical area 262 in which wirings for electrically connecting the memory chips 350a, 350b, 350c, and 350d, respectively, are disposed. Additionally, each of the first to fourth logic chips 250a, 250b, 250c, and 250d may include a wiring area 260 in which wirings for electrically connecting the first to fourth logic chips 250a, 250b, 250c, and 250d on different interposers are disposed.

The physical area 262 of each of the first to fourth logic chips 250a, 250b, 250c, and 250d may be adjacent to the third chip mounting area A3. The wiring area 260 of each of the first to fourth logic chips 250a, 250b, 250c, and 250d may be adjacent to the second chip mounting area A2. The wiring area 260 of the first logic chip 250a and the wiring area 260 of the third logic chip 250c may be opposite to each other in the second direction. The wiring area 260 of the second logic chip 250b and the wiring area 260 of the fourth logic chip 250d may be opposite to each other in the second direction.

The connection chip 300 may be provided (e.g., bonded) on each of the first to fourth interposers 200a, 200b, 200c, and 200d, and may be electrically connected to the first to fourth interposers 200a, 200b, 200c, and 200d. In example embodiments, the connection chip 300 may have a bridge shape for connecting the first to fourth interposers 200a, 200b, 200c, and 200d.

The connection chip 300 may include connection wirings for electrically connecting the first to fourth logic chips 250a, 250b, 250c, and 250d.

The connection chip 300 may be disposed on the second chip mounting areas A2 of the first to fourth interposers 200a, 200b, 200c, and 200d and between the second chip mounting areas A2 of the first to fourth interposers 200a, 200b, 200c and 200d.

The semiconductor package 10a may include the four interposers 200a, 200b, 200c, and 200d being spaced apart from each other on one package substrate 100, and four logic chips 250a, 250b, 250c, 250d may be electrically connected by one connection chip 300. Accordingly, the semiconductor package 10a may be manufactured to have high yield, and the semiconductor package 10 may have high reliability.

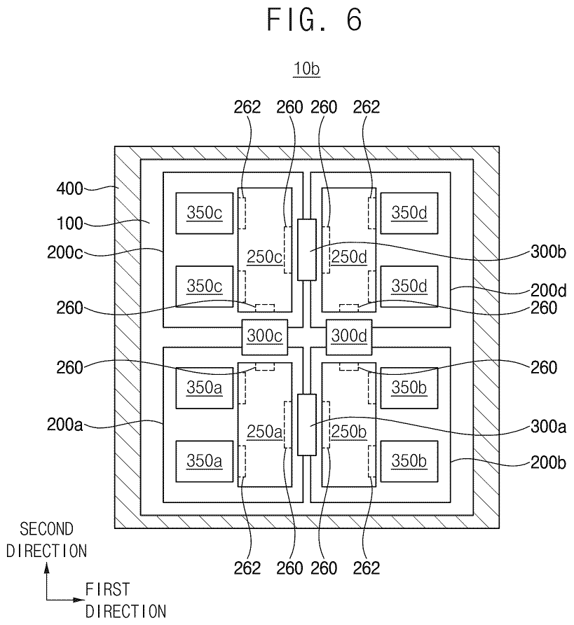

FIG. 6 is a schematic plan view illustrating a semiconductor package 10b according to example embodiments.

Referring to FIG. 6, the first to fourth interposers 200a, 200b, 200c, and 200d may be disposed on the package substrate 100.

The first logic chip 250a and the first memory chips 350a may be disposed on the first interposer 200a. The second logic chip 250b and the second memory chips 350b may be disposed on the second interposer 200b. The third logic chip 250c and the third memory chips 350c may be disposed on the third interposer 200c. The fourth logic chip 250d and the fourth memory chips 350d may be disposed on the fourth interposer 200d.

The arrangement of the interposers, the logic chips, and the memory chips may be substantially the same as that described with reference to of FIG. 5, except for the use of a plurality of connection chips.

A plurality of connection chips 300a, 300b, 300c and 300d may be on the first to fourth interposers 200a, 200b, 200c and 200d, and each of the plurality of connection chips 300a, 300b, 300c and 300d may electrically connect at least two of the first to fourth interposers 200a, 200b, 200c, 200d. The first to fourth logic chips 250a, 250b, 250c, and 250d may be electrically connected to each other by the plurality of connection chips 300a, 300b, 300c, and 300d. In this case, each of the wiring areas 260 included in the first to fourth logic chips 250a, 250b, 250c, and 250d may be disposed to face the connection chips 300a, 300b, 300c, and 300d.

In example embodiments, first to fourth connection chips 300a, 300b, 300c, and 300d may be disposed on the first to fourth interposers 200a, 200b, 200c, and 200d. In example embodiments, each of the first to fourth connection chips 300a, 300b, 300c, and 300d may connect two neighboring (i.e., adjacent) interposers 200a, 200b, 200c, and 200d to each other to have a bridge shape.

The first connection chip 300a may be provided on the first and second interposers 200a and 200b, respectively, and may electrically connect the first and second interposers 200a and 200b. The first connection chip 300a may include connection wirings for electrically connecting the first and second logic chips 250a and 250b.

The second connection chip 300b may be provided on the third and fourth interposers 200c and 200d, respectively, and may electrically connect the third and fourth interposers 200c and 200d. The second connection chip 300b may include connection wirings for electrically connecting the third and fourth logic chips 250c and 250d.

The third connection chip 300c may be provided on the first and third interposers 200a and 200c, respectively, and may electrically connect the first and third interposers 200a and 200c. The third connection chip 300c may include connection wirings for electrically connecting the first and third logic chips 250a and 250c.

The fourth connection chip 300d may be provided on the second and fourth interposers 200b and 200d, respectively, and may electrically connect the second and fourth interposers 200b and 200d. The fourth connection chip 300d may include connection wirings for electrically connecting the second and fourth logic chips 250b and 250d.

The semiconductor package 10b may include four interposers 200a, 200b, 200c and 200d spaced apart horizontally from each other on one package substrate 100. Additionally, four logic chips 250a, 250b, 250c and 250d may be electrically connected by the plurality of connection chips 300a, 300b, 300c and 300d. Accordingly, the semiconductor package 10b may be manufactured to have high yield, and the semiconductor package 10b may have high reliability.

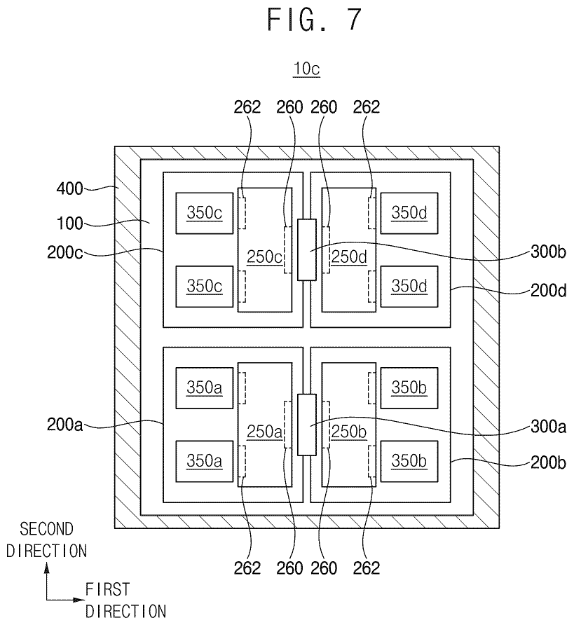

FIG. 7 is a schematic plan view illustrating a semiconductor package 10c according to example embodiments.

Referring to FIG. 7, the first to fourth interposers 200a, 200b, 200c, and 200d may be disposed on the package substrate 100.

The first logic chip 250a and the first memory chips 350a may be disposed on the first interposer 200a. The second logic chip 250b and the second memory chips 350b may be disposed on the second interposer 200b. The third logic chip 250c and third memory chips 350c may be disposed on the third interposer 200c. The fourth logic chip 250d and the fourth memory chips 350d may be disposed on the fourth interposer 200d.

The arrangement of the interposers, logic chips, and memory chips may be the same as that described with reference to FIG. 5, except that only two connection chips 300a, 300b are used and adjacent interposers are not connected in the second direction.

The first connection chip 300a may be disposed on the first and second interposers 200a and 200b, respectively, and may connect the first and second interposers 200a and 200b, adjacent to each other in the first direction, to each other. The second connection chip 300b may be disposed on the third and fourth interposers 200c and 200d, respectively, and may connect the third and fourth interposers 200c and 200d, adjacent to each other in the first direction, to each other. The first connection chip 300a may have a bridge shape for connecting the first and second interposers 200a and 200b. The second connection chip 300b may have a bridge shape for connecting the third and fourth interposers 200c and 200d.

The first connection chip 300a may electrically connect the first and second interposers 200a and 200b. The first connection chip 300a may include connection wirings for electrically connecting the first and second logic chips 250a and 250b.

The second connection chip 300b may electrically connect the third and fourth interposers 200c and 200d. The second connection chip 300b may include connection wirings for electrically connecting the third and fourth logic chips 250c and 250d.

The semiconductor package 10c may include four interposers 200a, 200b, 200c, and 200d spaced apart from each other on one package substrate 100. The first and second logic chips 250a and 250b may be electrically connected by the first connection chip 300a. The third and fourth logic chips 250c and 250d may be electrically connected by the second connection chip 300b. Accordingly, the semiconductor package 10c may be manufactured to have high yield, and the semiconductor package 10c may have high reliability.

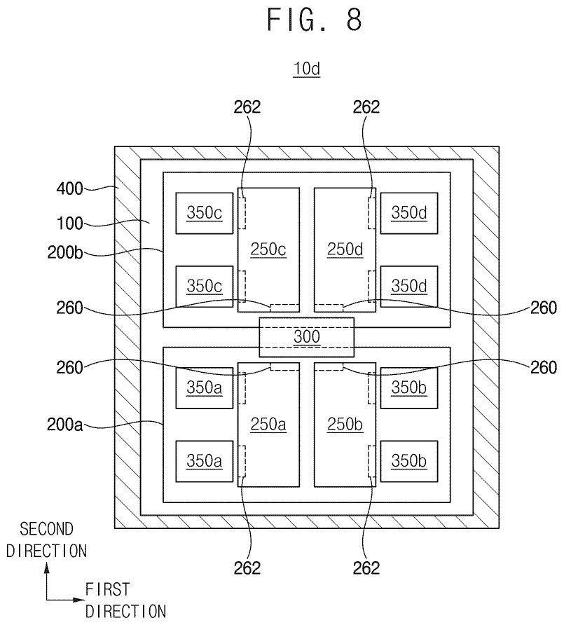

FIG. 8 is a schematic plan view illustrating a semiconductor package 10d according to example embodiments.

Referring to FIG. 8, two interposers may be provided on the package substrate 100, and the two interposers are referred to as first and second interposers 200a and 200b, respectively.

The first and second logic chips 250a and 250b and the first and second memory chips 350a and 350b may be disposed on the first interposer 200a. The third and fourth logic chips 250c and 250d and the third and fourth memory chips 350c and 350d may be disposed on the second interposer 200b. That is, two logic chips 250a and 250b and the corresponding plurality of memory chips 350a and 350b may be disposed on the first interposer 200a, and two logic chips 250c and 250d and the corresponding memory chips 350c and 350d may be disposed on the second interposer 200b.

The connection chip 300 may be disposed on the first and second interposers 200a and 200b, and may electrically connect the first and second interposers 200a and 200b to each other. The connection chip 300 may electrically connect the first to fourth logic chips 250a, 250b, 250c, and 250d. The connection chip 300 may include connection wirings for electrically connecting the first to fourth logic chips 250a, 250b, 250c, and 250d.

The connection chip 300 may have a bridge shape for connecting the first and second interposers 200a and 200b.

The semiconductor package 10d may have two interposers 200a and 200b spaced apart from each other on one package substrate 100 in the second direction, and two logic chips and their corresponding memory chips may be disposed on each of the interposers. Additionally, the logic chips 250a, 250b, 250c, and 250d may be electrically connected by the connection chips 300. Accordingly, the semiconductor package 10d may be manufactured to have high yield, and the semiconductor package 10d may have high reliability.

Hereinafter, a method for manufacturing the semiconductor package shown in FIG. 1 may be described.

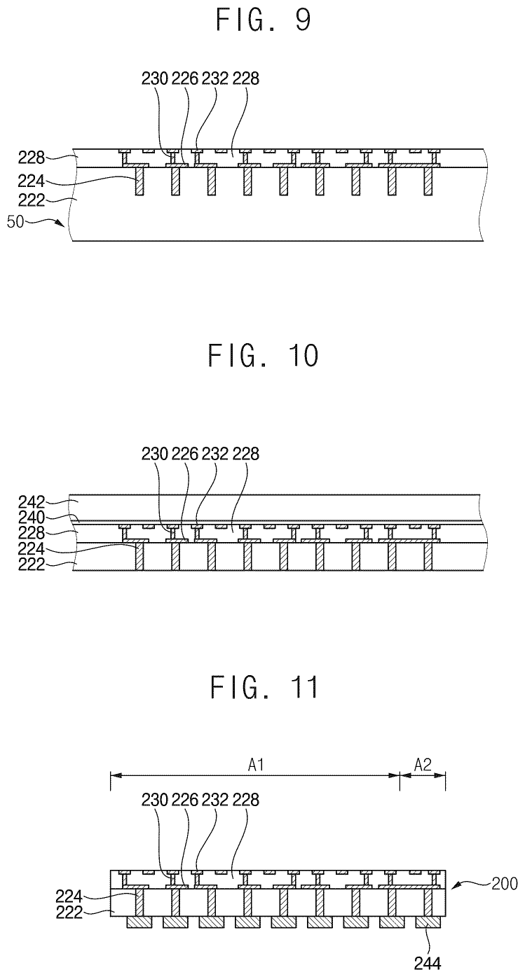

FIGS. 9 to 22 are schematic cross-sectional views and schematic plan views illustrating intermediate processes in an illustrative method of manufacturing a semiconductor package according to example embodiments.

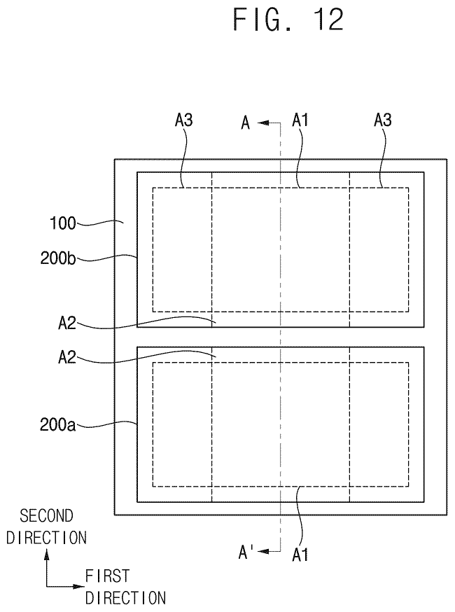

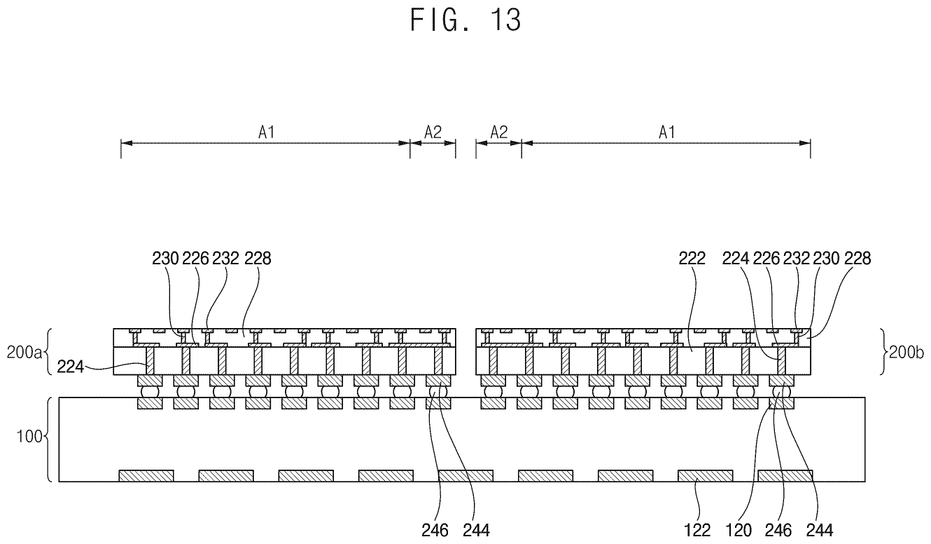

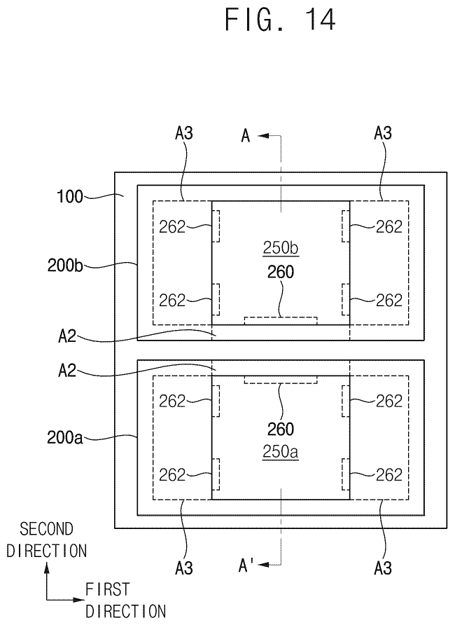

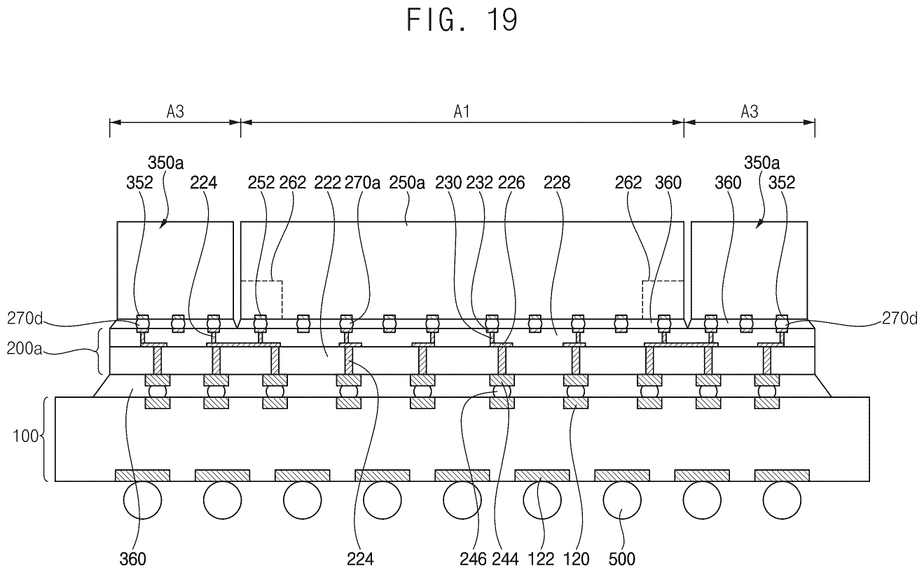

FIGS. 9 to 11, 13, 15, 17, 19, 20 and 22 are schematic cross-sectional views, and FIGS. 12, 14, 16, 18 and 21 are schematic plan views. FIGS. 13, 15, 17, 20 and 22 are schematic cross-sectional views taken along line A-A′ of the plan view of FIG. 1, and FIG. 19 is a cross-sectional view taken along line B-B′ of the plan view of FIG. 1.

Referring to FIG. 9, through silicon vias 224 (TSVs) may be formed through an upper inner portion of an interposer substrate 50 from an upper surface of the interposer substrate 50. The interposer substrate 50 may include, e.g., silicon.

In example embodiments, pad patterns 226 may be formed on an upper surface of the TSVs 224, respectively.

An insulation layer 228 and wiring patterns 230 positioned in the insulation layer 228 may be formed on the upper surface of the interposer substrate 50. The wiring patterns 230 may be a redistribution layer. A first bonding pad 232 may be formed on the redistribution layer.

In the interposer substrate 50, a portion for forming the TSV 224 may be referred to as an upper portion, and a portion below a bottom of the TSV 224 may be referred to as a lower portion.

Referring to FIG. 10, a carrier substrate 242 may be provided (i.e., attached) on the interposer substrate 50.

In example embodiments, an adhesive layer 240 may be formed on the insulation layer 228 and the first bonding pad 232 on the interposer substrate 50, and the carrier substrate 242 may be attached on the interposer substrate 50 using the adhesive layer 240. The carrier substrate 242 may include, e.g., metal, glass, ceramic, etc. The adhesive layer 240 may be, e.g., an adhesive tape or adhesive liquid.

A lower portion of the interposer substrate 50 may be removed until the bottom of the TSVs 224 may be exposed. Accordingly, a cross-sectional thickness (i.e., in a vertical direction) of the interposer substrate 50 may be decreased to form a silicon base portion. The bottom of the TSVs 224 may be exposed by a lower surface of the silicon base portion 222. The removing process may include, e.g., mechanical polishing, chemical mechanical polishing (CMP), or a separation process including forming a soft layer within the interposer substrate 50, e.g., a smart cut process.

Referring to FIG. 11, a second bonding pad 244 may be formed on the bottom of the interposer substrate 50 to be electrically connected to the bottom of the TSVs 224.

The carrier substrate 242 may be removed. Additionally, the adhesive layer 240 may be removed together. Thereafter, the interposer substrate 50 may be cut (e.g., diced) to form a plurality of interposers 200, which may be referred to individually as 200a and 200b (i.e. individual interposers).

Each of the interposers 200a and 200b may include the silicon base portion 222, the first bonding pad 232, the second bonding pad 244, the TSV 224, and the redistribution layer.

The first bonding pad 232, the second bonding pad 244, the TSV 224, and the redistribution layer may have a wiring structure for an interconnection between logic chips, memory chips, connection chips and the package substrate 100 included in the semiconductor package.

As shown in FIG. 12, each of the interposers 200a and 200b may have a first chip mounting area A1 on which the logic chips (e.g., 250a and 250b, respectively, of FIG. 1) are mounted, a second chip mounting area A2 on which the connection chip (e.g., 300 of FIG. 1) is mounted, and a third chip mounting area A3 on which the memory chips (e.g., 350a and 350b of FIG. 1) are mounted.

In the first and second interposers 200a and 200b, wirings for connecting the logic chips and the package substrate 100, wirings for electrically connecting the logic chips and the memory chips, and wirings for electrically connecting the logic chips and the connection chips may be included in the first chip mounting area A1. In the first and second interposers 200a and 200b, wirings for electrically connecting the logic chips may be included in the second chip mounting area A2. In the first and second interposers 200a and 200b, wirings for electrically connecting the memory chips and the package substrate 100 and wirings for electrically connecting the logic chips and the memory chips may be included in the third chip mounting area A3.

Referring to FIGS. 12 and 13, the plurality of interposers 200a and 200b may be bonded on the package substrate 100, respectively. That is, the plurality of interposers 200a and 200b may be arranged on one package substrate 100 while being spaced apart from each other in a horizontal direction.

The package substrate 100 may include the interposers and internal wirings for electrical connection. First substrate pads 120 may be formed on an upper surface of the package substrate 100, and second substrate pads 122 may be formed on a lower surface of the package substrate 100.

In example embodiments, the number of interposers 200a and 200b bonded on the package substrate 100 may be equal to the number of logic chips included in the semiconductor package. In some example embodiments, the number of interposers 200a and 200b bonded on the package substrate 100 may be smaller than the number of logic chips included in the semiconductor package.

In FIGS. 12 and 13, two interposers (200a and 200b) disposed on the package substrate 100 are shown. The two interposers are referred to as a first interposer 200a and a second interposer 200b. However, the number of interposers disposed on the package substrate 100 may not be limited thereto.

In example embodiments, the first and second interposers 200a and 200b may be provided (e.g., mounted) on the package substrate 100 through conductive bumps 246. The conductive bumps 246 may be disposed between the first substrate pad 120 of the package substrate 100 and the second bonding pad 244 of the first and second interposers 200a and 200b. For example, the conductive bump 246 may include copper pillars and C4 solder bumps. The first and second interposers 200a and 200b may be attached on the package substrate 100 by, e.g., a thermal compression process.

The first and second interposers 200a and 200b may be bonded on the package substrate 100 so that the second chip mounting area A2 of the first interposer 200a and the second chip mounting area A2 of the second interposer 200b may be opposite, in the horizontal direction, to each other. The second chip mounting area A2 of the first interposer 200a and the second chip mounting area A2 of the second interposer 200b may be adjacent to each other.

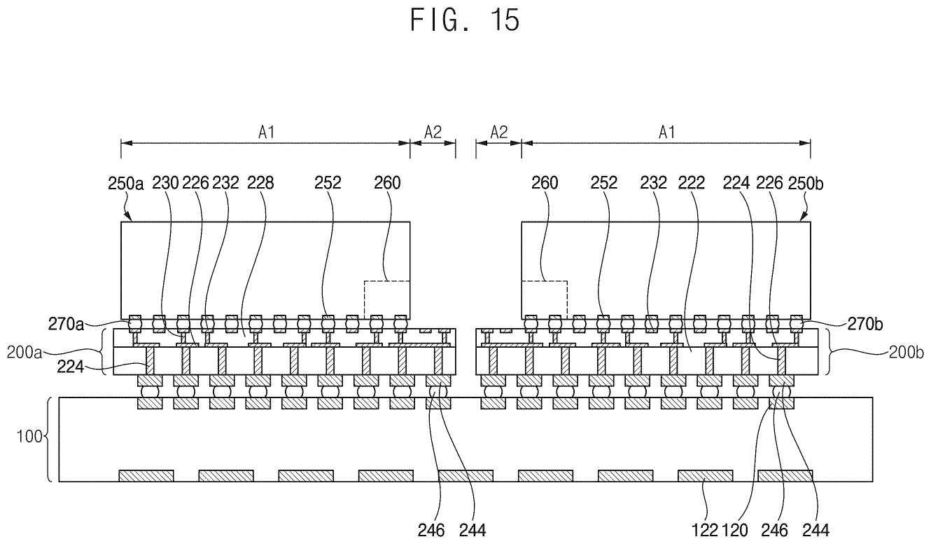

Referring to FIGS. 14 and 15, the first logic chip 250a may be mounted on the first chip mounting area A1 of the first interposer 200a. The second logic chip 250b may be mounted on the first chip mounting area A1 of the second interposer 200b.

In example embodiments, the first and second logic chips 250a and 250b may be mounted by a flip-chip bonding process, although embodiments are not limited thereto.

The first chip pads 252 of the first logic chip 250a may be electrically connected to the first bonding pads 232 of the first interposer 200a through first solder bumps 270a. The first chip pads 252 of the second logic chip 250b may be electrically connected to the first bonding pads 232 of the second interposer 200b through second solder bumps 270b. The first and second solder bumps 270a and 270b may include micro bumps, although embodiments are not limited thereto. For example, the first and second solder bumps 270a and 270b may have a stacked structure of a copper pillar, a micro solder, and a copper pillar.

Each of the logic chips 250a and 250b may include a physical area (PHY) 262 on which wirings for electrically connecting the memory chips (e.g., 350a and 350b in FIG. 1) are disposed. Additionally, each of the logic chips 250a and 250b may include a wiring area 260 on which wiring for electrically connecting the logic chips 250a and 250b on different interposers are disposed.

In each of the first and second logic chips 250a and 250b, the physical area 262 may face the third chip mounting area A3. The physical area 262 may be adjacent to the third chip mounting area A3 in the first direction. The wiring area 260 of the first logic chip 250a and the wiring area 260 of the second logic chip 250b may be opposite to each other in the second direction. The wiring area 260 of the first and second logic chips 250a and 250b may be adjacent to the second chip mounting area A2.

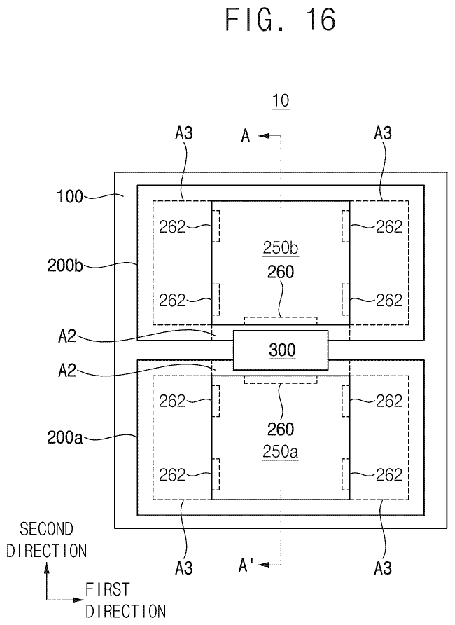

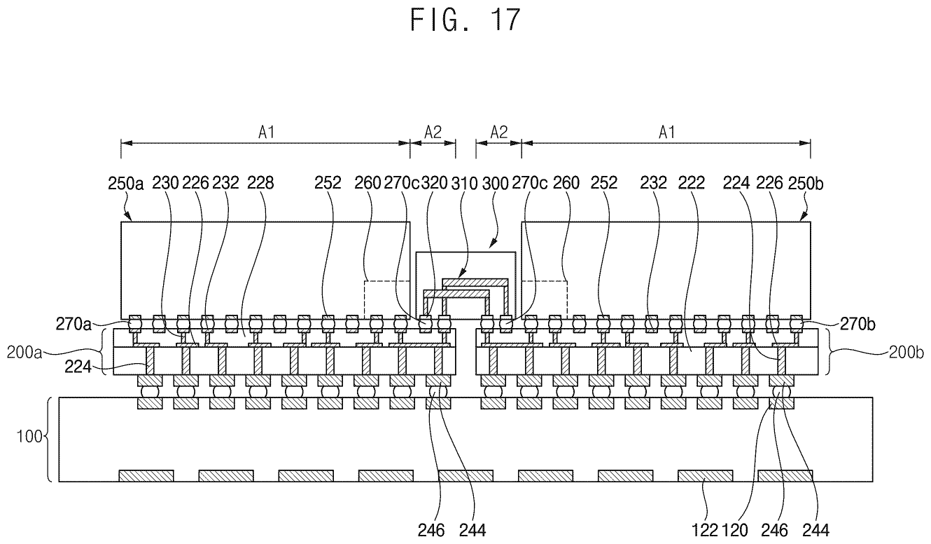

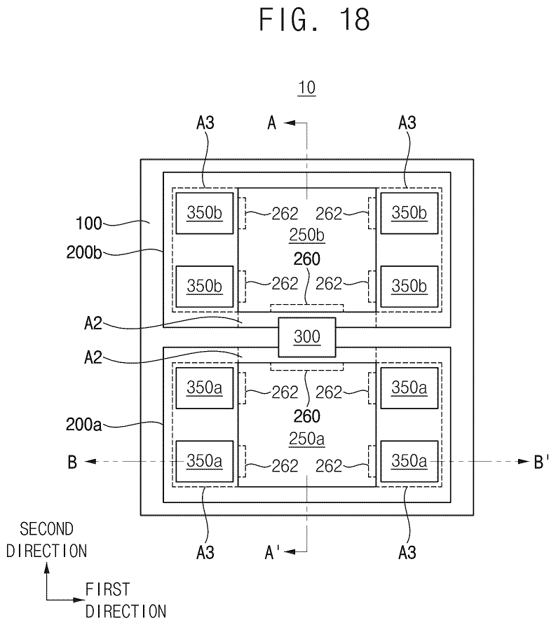

Referring to FIGS. 16 and 17, a connection chip 300 may be provided (e.g., mounted) on the second chip mounting area A2 of the first interposer 200a and the second chip mounting area A2 of the second interposer 200b. The connection chip 300 may have a bridge shape electrically connecting the first and second interposers 200a and 200b.

A connection wiring 310 for electrically connecting the first logic chip 250a and the second logic chip 250b may be included in the connection chip 300. Accordingly, the first logic chip 250a on the first interposer 200a and the second logic chip 250b on the second interposer 200b may be electrically connected by the connection chip 300.

The connection chip 300 may be disposed on the second chip mounting area A2 of the first interposer 200a, the second chip mounting area A2 of the second interposer 200b, and a region between the second chip mounting areas A2 of the first and second interposers 200a and 200b (i.e., the region separating the first and second interposers 200a and 200b in the second direction). The connection chip 300 may face the second chip mounting area A2 of the first interposer 200a, the second chip mounting area A2 of the second interposer 200b, and the region between the second chip mounting areas A2 of the first and second interposers 200a and 200b in a vertical direction.

In example embodiments, the connection chip 300 may be mounted on the second chip mounting area A2 of the first interposer 200a and the second chip mounting area A2 of the second interposer 200b by a flip-chip bonding process. Third chip pads 320 of the connection chip 300 may be connected to the first bonding pads 232 of the first interposer 200a and the first bonding pads 232 of the second interposer 200b by the third solder bumps 270c. The third solder bump 270c may include, e.g., a micro bump. For example, the third solder bump 270c may have a vertically stacked structure of a copper pillar, a micro solder, and a copper pillar.

Referring to FIGS. 18 and 19, first memory chips 350a may be provided (e.g., mounted) on the third chip mounting area A3 of the first interposer 200a. Second memory chips 350b may be mounted on the third chip mounting area A3 of the second interposer 200b.

In example embodiments, the first and second memory chips 350a and 350b may be mounted by a flip-chip bonding process.

Second chip pads 352 of the first memory chip 350a may be electrically connected to the first bonding pads 232 of the first interposer 200a by fourth solder bumps 270d. The second chip pads 352 of the second memory chip 350b may be electrically connected to the first bonding pads 232 of the second interposer 200b by the fourth solder bumps 270d. The fourth solder bump 270d may include, e.g., a micro bump. For example, the fourth solder bump 270d may have a vertically stacked structure of a copper pillar, a micro solder, and a copper pillar.

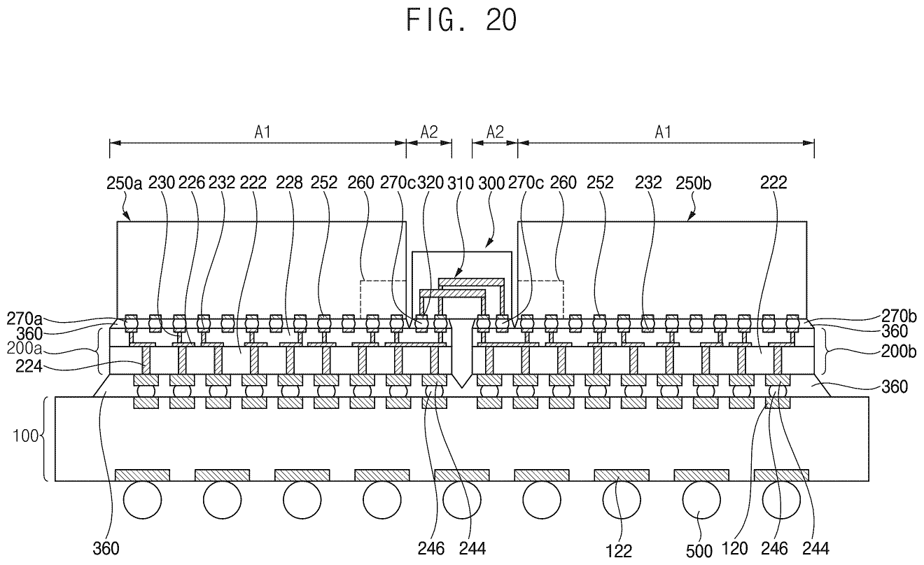

Referring to FIG. 20, an underfill member 360 may at least partially fill a space between the first interposer 200a and the package substrate 100 and a space between the second interposer 200b and the package substrate 100. The underfill member 360 may at least partially fill a space between the first interposer 200a and the first logic chip 250a and a space between the second interposer 200b and the second logic chip 250b. Additionally, the underfill member 360 may at least partially fill a space between the first interposer 200a and the connection chip 300 and a space between the second interposer 200b and the connection chip 300.

The underfill member 360 may include a material having a high fluidity to fill the space between the interposers 200a and 200b and the package substrate 100, the space between the interposers 200a and 200b and the logic chips 250a and 250b, and the space between the interposers 200a and 200b and the connection chip 300. For example, the underfill member 360 may include an adhesive including an epoxy material. The underfill member 360 may fill spaces under and above the interposers.

Subsequently, external bumps 500 may be formed on the second substrate pads 122.

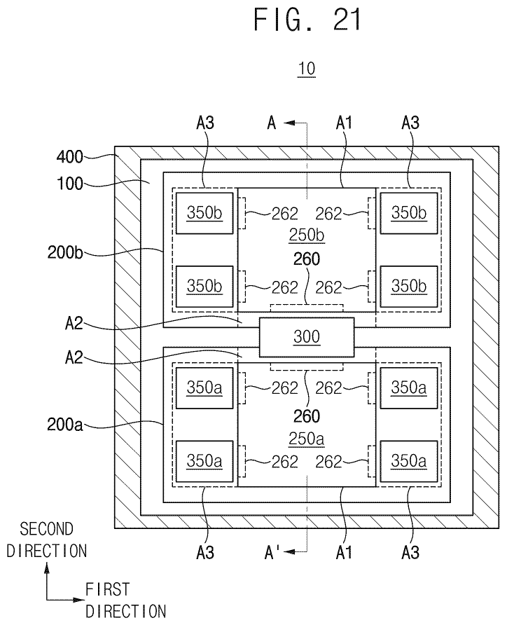

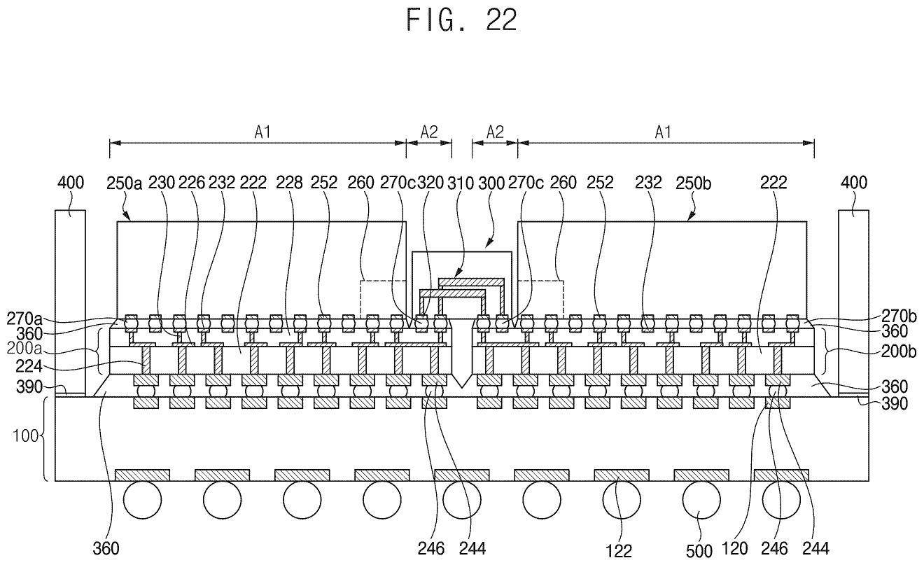

Referring to FIGS. 21 and 22, a stiffener structure 400 surrounding (i.e., extending around) an edge (i.e., periphery) of the package substrate 100 may be bonded on the package substrate 100. The stiffener structure 400 may be bonded on the package substrate 100 using an adhesive 390. The term “surrounding” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

Since the semiconductor package has the plurality of interposers disposed on the package substrate, a horizontal area of each of the interposers (i.e., individual interposer) disposed on the package substrate may be decreased compared to a case where the semiconductor package includes one interposer. Accordingly, process defects of each of the interposers may be decreased and a yield of the interposers may be increased. Therefore, process defects of the semiconductor package may be decreased.

While the present inventive concepts have been shown and described with reference to example embodiments thereof, it will be understood by those of ordinary skill in the art that various changes in form and details may be made thereto without departing from the scope of the present inventive concepts as set forth by the following claims.

What is claimed is:

1. A semiconductor package, comprising:
a package substrate;
a first interposer and a second interposer on the package substrate, the first interposer and the second interposer being spaced apart from each other in a horizontal direction parallel to an upper surface of the package substrate;
a first logic chip and first memory chips on the first interposer;
a second logic chip and second memory chips on the second interposer; and
a connection chip on the first and second interposers and electrically connecting the first and second interposers,
wherein the connection chip electrically connects the first and second logic chips, and is between the first and second logic chips.

2. The semiconductor package of claim 1, wherein a first wiring electrically connecting the first logic chip and the package substrate and a second wiring electrically connecting the first logic chip and the connection chip are included in the first interposer, and
wherein a third wiring electrically connecting the second logic chip and the package substrate and a fourth wiring electrically connecting the second logic chip and the connection chip are included in the second interposer.

3. The semiconductor package of claim 1, wherein the connection chip includes connection wirings for electrically connecting the first and second logic chips.

4. The semiconductor package of claim 1, wherein the first logic chip and the first memory chips are arranged in the horizontal direction on the first interposer, and
wherein the second logic chip and the second memory chips are arranged in the horizontal direction on the second interposer.

5. The semiconductor package of claim 1, wherein the first logic chip, the first memory chips, and the connection chip on the first interposer are electrically connected to the first interposer by a plurality of first solder bumps on corresponding first bonding pads of the first interposer, and
wherein the second logic chip, the second memory chips, and the connection chip on the second interposer are electrically connected to the second interposer by a plurality of second solder bumps on corresponding first bonding pads of the second interposer.

6. The semiconductor package of claim 5, further comprising an underfill member on the first and second interposers,
wherein the underfill member at least partially fills a space between the first interposer and the first logic chip, a space between the first interposer and the connection chip, a space between the second interposer and the second logic chips and a space between the second interposer and the connection chip.

7. The semiconductor package of claim 1, wherein the first and second interposers are mounted on the package substrate through conductive bumps.

8. The semiconductor package of claim 1, further comprising an underfill member between the first interposer and the package substrate and between the second interposer and the package substrate.

9. The semiconductor package of claim 1, wherein the first logic chip includes a first physical area in which first wirings for electrically connecting the first memory chips are disposed and a first wiring area in which second wirings for electrically connecting the first and second logic chips are disposed, and
wherein the second logic chip includes a second physical area in which third wirings for electrically connecting the second memory chips are disposed and a second wiring area in which fourth wirings for electrically connecting the first and second logic chips are disposed.

10. The semiconductor package of claim 9, wherein the first wiring area and the second wiring area are adjacent to each other in the horizontal direction.

11. The semiconductor package of claim 9, wherein the first and second wiring areas are adjacent to the connection chip in the horizontal direction.

12. The semiconductor package of claim 1, wherein the first and second interposers include silicon interposers.

13. A semiconductor package, comprising:
a package substrate;
a plurality of interposers spaced apart from each other in a horizontal direction on the package substrate;
at least one logic chip and a plurality of memory chips on each of the interposers; and
a connection chip on at least two of the interposers adjacent to each other in the horizontal direction, the connection chip having a bridge shape to electrically connect the at least two of the interposers to each other, and
wherein the connection chip is electrically connected to the at least one logic chip on each of the at least two of the interposers.

14. The semiconductor package of claim 13, wherein a first wiring electrically connecting the at least one logic chip on each of the interposers and the package substrate and a second wiring electrically connecting the at least one logic chip on each of the interposers and the connection chip are included in each of the interposers.

15. The semiconductor package of claim 13, wherein the connection chip includes connection wirings for electrically connecting the at least one logic chip on each of the interposers to each other.

16. The semiconductor package of claim 13, wherein the at least one logic chip on each of the interposers includes a physical area in which first wirings for electrically connecting the plurality of memory chips are disposed and a wiring area in which second wirings for electrically connecting the at least one logic chip on adjacent ones of the plurality of interposers are disposed.

17. The semiconductor package of claim 13, wherein the interposers include silicon interposers.

18. A semiconductor package, comprising:
a package substrate;
a first interposer on the package substrate;
a second interposer on the package substrate and spaced apart from the first interposer in a horizontal direction parallel to an upper surface of the package substrate;
a first logic chip on the first interposer;
first memory chips on the first interposer and spaced apart in the horizontal direction from at least one sidewall of the first logic chip, the first memory chips being electrically connected to the first logic chip;
a second logic chip on the second interposer, the second logic chip facing the first logic chip in the horizontal direction;
second memory chips on the second interposer and spaced apart from at least one sidewall of the second logic chip, the second memory chips being electrically connected to the second logic chip;
a connection chip between the first and second logic chips on the first and second interposers, respectively, the connection chip having a bridge shape to electrically connect the first and second interposers to each other, and the connection chip including a wiring electrically connecting the first and second logic chips; and
an underfill member at least partially filling a space between the first interposer and the first logic chip, a space between the first interposer and the connection chip, a space between the second interposer and the second logic chip, a space between the second interposer and the connection chip, a space between the first interposer and the package substrate, and a space between the second interposer and the package substrate.

19. The semiconductor package of claim 18, wherein a first wiring electrically connecting the first logic chip and the package substrate and a second wiring electrically connecting the first logic chip and the connection chip are included in the first interposer, and
wherein a third wiring electrically connecting the second logic chip and the package substrate and a fourth wiring electrically connecting the second logic chip and the connection chip are included in the second interposer.

20. The semiconductor package of claim 18, wherein the connection chip includes connection wirings for electrically connecting the first and second logic chips.
